(19) United States
(12) Patent Application Publication
(10) Pub. No.: US 2017/0038030 A1
(43) Pub. Date: Feb. 9, 2017

(54) REFLECTIVE MATTE COATING FOR LIGHTING FIXTURE

(71) Applicant: GE Lighting Solutions, LLC, East Cleveland, OH (US)

(72) Inventors: Jon Bennett Jansma, Pepper Pike, OH (US); Gary Robert Allen, Euclid, OH (US); Martin Norman Hassink, East Cleveland, OH (US); Matthew A. Bugenske, East Cleveland, OH (US); Jianmin He, Orange, OH (US); Dengke Cai, Willoughby, OH (US); Walter John Skovron, Louisville, KY (US)

(21) Appl. No.: 14/819,467

(22) Filed: Aug. 6, 2015

(51) Int. Cl. F21V 7/22; C23C 16/44

(52) U.S. Cl. CPC F21V 7/22; C23C 16/44

(57) ABSTRACT

Provided is a reflective matte coating layer, a lighting fixture and a method that includes a metal layer including an inner surface and an outer surface, and a powder coating layer disposed on the outer surface of the metal layer, wherein an infrared (IR) gradient curing operation is performed on the inner surface of the metal layer, to form a reflective matte coating at an external surface of the lighting fixture.

### TECHNICAL FIELD

The present invention relates generally to a lighting fixture. In particular, the present invention relates reflective matte coating method for a lighting fixture.

### BACKGROUND OF THE INVENTION

A lighting fixture is designed to direct light to provide efficient illumination of objects or surface areas. An important component of the lighting fixture is a reflective surface, which may comprise a metal surface which provides directivity of the light produced by the light sources. The lighting fixture includes a base metal material which is typically coated with a reflective layer to provide visible light reflectivity at the surface and to protect the metal material from the environment.

The reflective layer is often applied as an adhesive film or as a single coating layer via a curing process. The use of thermal processes may result in a high gloss coating. Efficient total reflectivity and low gloss can be difficult to achieve with a single coating layer.

In light emitting diode (LED) applications, it is often desirable to achieve a low gloss (i.e., matte) coating in order to prevent the appearance of individual LED devices as reflected from the fixture surface. Therefore, in existing LED applications, implementation of thermal curing processes fails to result in a desired low gloss coating on the lighting fixture.

### SUMMARY OF THE EMBODIMENTS

Given the foregoing deficiencies, a need exists for a highly reflective matte coating using an infrared (IR) gradient curing method for a lighting fixture.

In one exemplary embodiment, a lighting fixture is provided. The lighting fixture includes a metal layer including an inner surface and an outer surface; and a powder coating layer disposed on the outer surface of the metal layer, wherein an IR gradient curing operation is performed on the inner surface of the metal layer, to form a reflective matte coating at an external surface of the lighting fixture.

In another exemplary embodiment, a reflective matte coating on a metal layer is provided. The reflective matte coating includes a powder coating layer formed of reflective material disposed on an outer surface of a metal layer, wherein the powder coating layer is adhered to the metal layer by performing an IR gradient curing operation on an inner surface of the metal layer opposite the outer surface, to form the reflective matte coating on an external surface of the metal layer.

The foregoing has broadly outlined some of the aspects and features of various embodiments, which should be construed to be merely illustrative of various potential applications of the disclosure. Other beneficial results can be obtained by applying the disclosed information in a different manner or by combining various aspects of the disclosed embodiments. Accordingly, other aspects and a more comprehensive understanding may be obtained by referring to the detailed description of the exemplary embodiments taken in conjunction with the accompanying drawings, in addition to the scope defined by the claims.

### BRIEF DESCRIPTION OF THE DRAWINGS

FIG. 1 is a schematic illustrating a reflective matte coating for a lighting fixture that can be implemented within one or more embodiments of the present invention.

FIG. 2 is a schematic illustrating an exemplary lighting system for implementing the reflective matte coating of FIG. 1 in accordance with one or more embodiments of the present invention.

FIG. 3 is a schematic illustrating another exemplary lighting system for implementing the reflective matte coating of FIG. 1 in accordance with one or more embodiments of the present invention.

FIG. 4 is a flow diagram for a reflective matte coating method that can be implemented within one or more embodiments of the present invention.

The drawings are only for purposes of illustrating preferred embodiments and are not to be construed as limiting the disclosure. Given the following enabling description of the drawings, the novel aspects of the present disclosure should become evident to a person of ordinary skill in the art. This detailed description uses numerical and letter designations to refer to features in the drawings. Like or similar designations in the drawings and description have been used to refer to like or similar parts of embodiments of the invention.

### DETAILED DESCRIPTION OF THE EMBODIMENTS

As required, detailed embodiments are disclosed herein. It must be understood that the disclosed embodiments are merely exemplary of various and alternative forms. As used herein, the word “exemplary” is used expansively to refer to embodiments that serve as illustrations, specimens, models, or patterns. The figures are not necessarily to scale and some features may be exaggerated or minimized to show details of particular components. In other instances, well-known components, systems, materials, or methods that are known to those having ordinary skill in the art have not been described in detail in order to avoid obscuring the present disclosure. Therefore, specific structural and functional details disclosed herein are not to be interpreted as limiting, but merely as a basis for the claims and as a representative basis for teaching one skilled in the art.

Embodiments of the present invention provide a reflective matte coating to be applied to a metal layer (e.g., a metal layer of a lighting fixture) including a powder coating layer that includes a reflective material and a binder content, wherein a single side IR gradient curing operation is performed on the outer metal surface coated with the powder coating layer, to thereby form the reflective matte coating on an external surface of the lighting fixture. It may be implemented within various types of lighting fixtures to provide efficient illumination of display and surface areas.

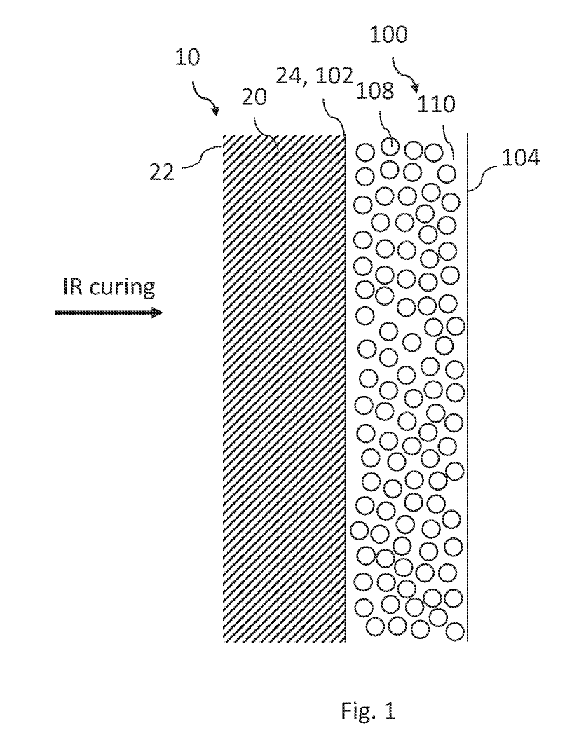

FIG. 1 is a schematic illustrating a reflective matte coating 100 for a lighting fixture 10 that can be implemented within one or more embodiments of the present invention. According to one or more embodiments, the reflective matte coating 100 may be applied to any metal layer of a system or device, for the purposes of provided a low gloss, matte finish to an external surface thereof. As shown, the lighting fixture 10, for example, includes a substrate formed of a metal substrate (i.e., an outer metal layer 20). The metal substrate may be formed of metals such as iron, steel, copper, and brass.

The outer metal layer can be formed of any suitable material for the purpose set forth herein. The outer metal layer 20 includes an inner surface 22 and an outer surface 24. The reflective matte coating 100 is formed on the outer surface 24 of the outer metal layer 20 of the lighting fixture 10. The reflective matte coating 100 is a powder coating layer formed of particles 108 (e.g., pigment particles) and a binder 110. The reflective matte coating 100 includes a first surface 102 adhered to the outer surface 24 of the outer metal layer 20, and a second surface 104 forming the matte external surface of the lighting fixture 10.

The particles 108 can be formed of a material such as metal oxide inorganic particles (e.g., TiO₂, Al₂O₃, Y₂O₃, ZrO₂, Ta₂O₅, Nb₂O₅), mixed metal oxide particles (MMOs), complex inorganic color pigments (CICPs), inorganic metal particles (e.g., BN, SiC), or other inorganic pigments known for white or colored pigmentation of coatings, or combinations thereof. The particles can also be formed of triglycidyliocyanurate.

The particles 108 are reflective to light having wavelengths in a certain range. A single type of pigment particle 108 can be used to provide a color to the reflective matte coating layer 100 by reflecting certain wavelengths of light. The pigment particles 108 can be included in the reflective matte coating layer 100 based on its composition, particle size, and/or density for its reflective characteristics.

The binder 110 can be any cross-linked binder that includes at least one of a cross-linkable polymeric binder that interacts with a cross-linker to from a 3-dimensional polymeric structure. The cross-linkable binder can include any suitable cross-linkable material prior to cross-linking and can encompass monomers, oligomers, and copolymers which can be further processed to form cross-linking binders that include materials such as reactive carboxyl groups (e.g., acrylics and meth-acrylic, polyurethanes, and ethylene-acrylic acid copolymers, reactive hydroxyl groups (e.g., polyesters such as polyethylene terephthalate), and combinations of these materials or any other materials suitable for the purpose set forth herein.

During manufacturing, a sheet of metal material is used to form the outer metal layer 20 of the lighting fixture 10. An IR gradient curing process is performed on the inner surface 22 of the metal layer 20 (as depicted by the arrow in FIG. 1). The IR gradient curing process is performed on a single side of the metal layer 20. As shown, IR gradient curing process is performed on the side opposite the side that the reflective matte coating layer 100 is formed. The IR gradient curing operation can be performed using IR emitters, or any other suitable devices for the purpose set forth herein.

The curing process can be performed at low temperatures ranging from approximately 100° C. or less. For example, the curing process may be performed at a range of approximately 75° C. to approximately 95° C. or higher. The curing process is performed for a duration ranging from approximately 5 minutes to approximately 2 hours, for example. However, the present invention is not limited hereto and the time may extend outside this range (i.e., less or greater). The curing operation can be performed in two operations, a first curing operation being performed at a temperature of approximately 75° C. to approximately 95° C. or higher for approximately 5 minutes to 2 hours, and a second curing operation being performed at a temperature of approximately 100° C. to approximately 150° C. or higher for approximately 5 minutes to 2 hours.

When the curing operation is performed, the outer metal layer 20 is directly heated from the inner side 22 thereof, causing gradient temperature from the inner surface 22 to the second surface 104 (e.g., outer external surface) of the reflective matte coating 100. Due to higher temperature at an interface of the outer surface 24 of the metal layer 20 and the first surface 102 of the reflective matte coating layer 100, more binder 110 flowing during crosslinking to enhance adhesion and due to lower temperature at the second surface 104 (e.g., the external surface), less binder 110 flowing during cross-linking, to thereby achieve a matte (e.g., low glossy) finish.

The reflective matte coating 100 can be formed of a thickness ranging from approximately 50 μm to approximately 250 μm. However, the present invention is not limited hereto and the thickness may vary, as needed.

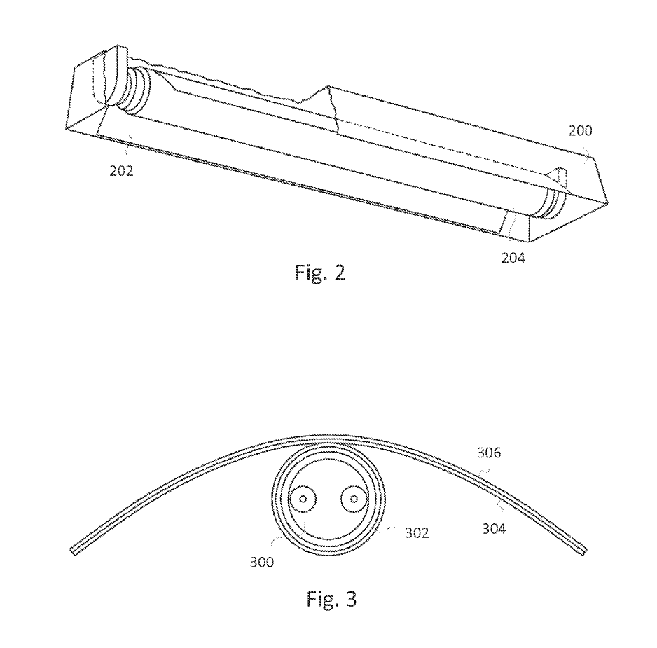

FIGS. 2 and 3 are schematics illustrating exemplary lighting systems for implementing the reflective matte coating of FIG. 1 in accordance with one or more embodiments of the present invention.

As shown in FIG. 2, a reflector 200 is positioned between a lamp (LED) 202 and a fixture housing 204. The reflector 200 can be permanently attached to the fixture housing 204. The reflector 200 can be formed of the reflective matte coating layer 100 as depicted in FIG. 1, facing the LED lamp 202.

As shown in FIG. 3, an LED lamp 300 has a collar 302 disposed surrounding the lamp 300. The collar 302 can be a flexible plastic material glued into a ring. A reflector sheet 306 can be constructed from a metal substrate and a reflective matte coating 304 formed similar to the reflective matte coating layer 100 depicted in FIG. 1.

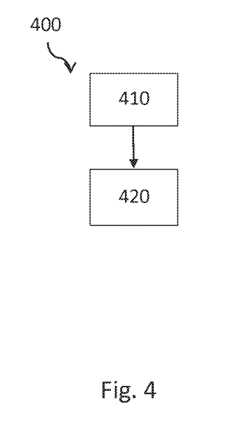

FIG. 4 is a flow diagram for a reflective matte coating method 400 that can be implemented within one or more embodiments of the present invention.

As shown in FIG. 4 with reference to FIG. 1, the method 400 begins at operation 410 where disposing a powder coating layer formed of a reflective material and binder onto an outer metal layer of a lighting fixture.

From operation 410, the process continues to operation 420 where an IR gradient curing operation is performed on an inner surface of the outer metal layer of the lighting fixture, to adhere the powder coating layer to the outer metal layer and provide a reflective matte coating at the external surface of the lighting fixture.

Embodiments of the present invention provide the advantages of forming a reflective matte coating layer on a lighting fixture by performing an IR gradient curing operation on a single side of the outer metal layer of the lighting fixture. The embodiments provide advantages of more uniform temperature distribution due to high energy exposure on the thermal conductive substrate (e.g., the outer metal layer) and good surface finish.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A lighting fixture comprising:
a metal layer including an inner surface and an outer surface; and
a powder coating layer disposed on the outer surface of the metal layer, wherein an infrared (IR) gradient curing operation is performed on the inner surface of the metal layer, to form a reflective matte coating at an external surface of the lighting fixture.

2. The lighting fixture of claim 1, wherein the powder coating layer is formed of a reflective material including a plurality of particles and a binder, wherein the powder coating layer adheres to the outer surface of the metal layer due to the IR gradient curing operation.

3. The lighting fixture of claim 2, wherein the IR gradient curing operation is performed at a temperature ranging from approximately 75° C. to approximately 95° C. or higher.

4. The lighting fixture of claim 3, wherein the IR gradient curing operation is performed for a duration of approximately 5 minutes to approximately 2 hours.

5. The lighting fixture of claim 2, wherein the IR gradient curing operation is performed in a two-step process, wherein a first curing operation is performed at a temperature of approximately 75° C. to approximately 95° C. or higher for a duration of approximately 5 minutes to approximately 2 hours, and a second curing operation is performed at a temperature of approximately 100° C. to approximately 150° C. or higher for a duration of approximately 5 minutes to approximately 2 hours.

6. The lighting fixture of claim 1, wherein during the IR gradient curing operation, a gradient temperature occurs from the inner surface of the metal layer to the external surface of the lighting fixture.

7. The lighting fixture of claim 2, wherein due to the IR gradient curing operation, a binder flow is higher at an interface between the outer layer of the metal layer and the first surface of the powder coating layer than a binder flow at the second surface of the powder coating.

8. A reflective matte coating, comprising:
a powder coating layer formed of reflective material disposed on an outer surface of a metal layer, wherein the powder coating layer is adhered to the metal layer by performing an infrared (IR) gradient curing operation on an inner surface of the metal layer opposite the outer surface, to form the reflective matte coating on the outer surface of the metal layer.

9. The reflective matte coating of claim 8, wherein the IR gradient curing operation is performed at a temperature ranging from approximately 75° C. to approximately 95° C. or higher.

10. The reflective matte coating of claim 9, wherein the IR gradient curing operation is performed for a duration of approximately 5 minutes to approximately 2 hours.

11. The reflective matte coating of claim 8, wherein the IR gradient curing operation is performed in a two-step process, wherein a first curing operation is performed at a temperature of approximately 75° C. to approximately 95° C. or higher for a duration of approximately 5 minutes to approximately 2 hours, and a second curing operation is performed at a temperature of approximately 100° C. to approximately 150° C. or higher for a duration of approximately 5 minutes to approximately 2 hours.

12. The reflective matte coating of claim 8, wherein during the IR gradient curing operation, a gradient temperature occurs from the inner surface of the metal layer to the outer surface of the metal layer.

13. The reflective matte coating of claim 8, wherein due to the IR gradient curing operation, a binder flow is higher at an interface between the outer layer of the metal layer and the first surface of the powder coating layer than a binder flow at the second surface of the powder coating layer.

14. A reflective matte coating method, comprising:
disposing a powder coating layer formed of a reflective material and binder onto a metal layer; and
performing an IR gradient curing operation on an inner surface of the metal layer, to adhere the powder coating layer to the metal layer and form a reflective matte coating at an external surface of the metal layer.

15. The method of claim 14, wherein the IR gradient curing operation is performed at a temperature ranging from approximately 75° C. to approximately 95° C. or higher.

16. The method of claim 15, wherein the IR gradient curing operation is performed for a duration of approximately 5 minutes to approximately 2 hours.

17. The method of claim 14, wherein the IR gradient curing operation is performed in a two-step process, wherein a first curing operation is performed at a temperature of approximately 75° C. to approximately 95° C. or higher for a duration of approximately 5 minutes to approximately 2 hours, and a second curing operation is performed at a temperature of approximately 100° C. to approximately 150° C. or higher for a duration of approximately 5 minutes to approximately 2 hours.

18. The method of claim 14, wherein during the IR gradient curing operation, a gradient temperature occurs from the inner surface of the metal layer to an outer surface of the metal layer.

19. The method of claim 18, wherein due to the IR gradient curing operation, a binder flow is higher at an interface between the outer surface of the metal layer and a first surface of the powder coating layer than a binder flow at a second surface of the powder coating layer.
